(19) United States
(12) Patent Application Publication
(10) Pub. No.: US 2012/0295406 A1
(43) Pub. Date: Nov. 22, 2012

(54) CARBON NANOTUBE DISPERSION LIQUID AND METHOD FOR MANUFACTURING SEMICONDUCTOR DEVICE

(75) Inventors: Hideaki Numata, Minato-ku (JP); Hiroyuki Endoh, Minato-ku (JP)

(73) Assignee: NEC CORPORATION, Minato-ku, Tokyo (JP)

(21) Appl. No.: 13/522,906

(22) PCT Filed: Jan. 18, 2011
(86) PCT No.: PCT/JP2011/050764

§ 371 Date: Jul. 18, 2012

(30) Foreign Application Priority Data
Jan. 19, 2010 (JP) 2010-009253

(51) Int. Cl. H01B 1/24; H01L 21/336; B82Y 40/00; B82Y 99/00

(52) U.S. Cl. 438/158; 252/510; 257/E21.409; 977/742; 977/750

(57) ABSTRACT

A carbon nanotube dispersion liquid obtained by mixing carbon nanotubes, a first organic solvent that is a nonpolar solvent, and a second organic solvent that has a polarity higher than that of this first organic solvent and is compatible with this first organic solvent.

### TECHNICAL FIELD

The present invention relates to a carbon nanotube dispersion liquid and a method for manufacturing a semiconductor device.

### BACKGROUND ART

Thin film transistors (TETs) are widely used as pixel switching elements for displays, such as liquid crystal displays and EL displays. In addition, in recent years, TFTs have often been used for driver circuits for a pixel array on the same substrate.

A larger area is required of a display using such TFTs, but TFTs are usually fabricated on a glass substrate using amorphous or polycrystalline silicon and thus have the following problems in manufacture. First, a CVD apparatus used for the manufacture of TFTs is very expensive, and its maintenance cost is also high, and therefore, a larger area of a display involves a significant increase in manufacturing cost. Secondly, the process for forming a film of amorphous or polycrystalline silicon is performed at extremely high temperature, and therefore, usable substrate materials are limited, and the use of lightweight resin materials is difficult.

On the other hand, carbon nanotubes (CNTs) have high electrical conductivity and mechanical strength, and therefore, various uses utilizing the characteristics are studied. A CNT is a cylindrical carbon molecule including only carbon and is of a structure in which a graphene sheet formed of only six-membered rings of carbon atoms is rolled. A CNT that is formed in a cylindrical shape by rolling one graphene sheet is referred to as a single walled nanotube (SWNT), and a CNT in which a plurality of cylindrical carbon nanotubes with different diameters are laminated is referred to as a multi walled nanotube (MWNT). The diameter of an SWNT is about 1 nm, and the diameter of an MWNT is about several tens nm. CNTs include various carbon nanotubes with different helicities (chiralities), for example, a helical carbon nanotube, a zigzag carbon nanotube, and an armchair carbon nanotube, depending on differences in the direction of rolling a graphene sheet, that is, differences in the orientation of six-membered rings of carbon atoms with respect to the circumferential direction, other than differences in diameter. In particular, SWNTs show both properties of metallicity and semiconductivity depending on differences in helicity (chirality).

By randomly growing such SWNTs between source-drain electrodes, for example, by a chemical vapor deposition method (CVD), a field effect transistor including a channel layer formed of SWNTs can be fabricated. In addition, this channel layer formed of SWNTs can also be formed by applying or printing a dispersion liquid of SWNTs on a substrate. Non Patent Literature 1 describes that in a random network of CNTs formed in this manner, many contacts occur to form connections between the carbon nanotubes, and the random network of CNTs can be utilized for the channel layer of a thin film transistor.

On the other hand, various techniques for dispersing CNTs in a liquid are studied because CNTs have strong cohesion and tend to be bundles of several to several hundred CNTs in a liquid, and the CNTs aggregate and precipitate with the lapse of time.

Patent Literature 1 discloses a dispersion liquid including CNTs, an amide-based organic solvent, polyvinylpyrrolidone (PVP), and a nonionic surfactant. As the nonionic surfactant, a polyoxyethylene-based surfactant is used.

Patent Literature 2 discloses a hydrophilic dispersion liquid including CNTs, a dispersing agent, and a compound having a particular hydrophobic portion-hydrophilic portion-hydrophobic portion structure. As the dispersing agent, alkylbenzenesulfonate and/or alkyl ether sulfate are used.

Patent Literature 3 discloses a dispersion liquid of CNTs dispersed in a liquid including sodium dodecylbenzenesulfonate, as a CNT dispersion liquid used in a CNT fractionation method using an electrophoresis method.

### CITATION LIST

### Patent Literature

### Patent Literature 1: JP2005-154630A

### Patent Literature 2: JP2003-238126A

### Patent Literature 3: JP2005-95806A

### Non Patent Literature

### Non Patent Literature 1: E. S. Snow et al., Applied Physics Letters, vol. 82, No. 13, p. 2145, (2003)

### SUMMARY OF INVENTION

### Technical Problem

A random network of CNTs can be formed by the application or printing of a CNT dispersion liquid as described above. According to this method, a larger area of a display can be achieved at low cost, and the process temperature is low, and there are a few limitations on the substrate material. Therefore, the manufacturing cost can be significantly reduced compared with the method of forming silicon-based TFTs on a glass substrate.

However, a problem is that an ordinary CNT dispersion liquid includes a nonvolatile dispersing agent, and therefore, the dispersing agent remains after the CNT dispersion liquid is applied or printed and the solvent is removed. In particular, when the electrical conductivity of a CNT random network is utilized, this problem is a large obstacle.

Organic solvents in which CNTs can be dispersed without using a dispersing agent include 1,2-dichloroethane. The boiling point of 1,2-dichloroethane is 83.7° C., and therefore, 1,2-dichloroethane can be sufficiently volatilized. However, problems are that CNTs are not dispersed unless the CNT concentration is sufficiently low, and with such a CNT dispersion liquid, CNTs segregate easily after printing, and a random network with poor uniformity is formed.

FIG. 1 shows results of observing the state, after printing, of a CNT dispersion liquid using only 1,2-dichloroethane for a solvent without using a dispersing agent by a conductive atomic force microscope (C-AFM). A height difference image is shown on the left side (A) in FIG. 1, and a current image is shown on the right side (B). Dark color portions unevenly distributed in the current image show an actually current-carrying, active current channel. It appears that CNTs are distributed with good uniformity in the height difference image on the left side (A), but the current image on the right side (B) shows that the uniformity of the active current channel is low.

In addition, it is known that if the drying conditions of ink liquid drops are inappropriate during printing, ring-shaped stains referred to as coffee stains occur due to the effect of convection occurring inside the liquid drops. If the above CNT dispersion liquid using 1,2-dichloroethane is printed under such inappropriate conditions in which coffee stains occur, the uniformity is further degraded. FIG. 2 shows results of observing a coffee stain occurring in the printing of the above CNT dispersion liquid by a C-AFM. A height difference image is shown on the left side (A) in FIG. 2, and a current image is shown on the right side (B). In the current image of FIG. 2, current-carrying parts are shown by white portions. Portions where the density of CNTs is extremely large and portions with few CNTs occur in stripes. In the current-carrying portions, the CNT density is too large, and metallic electrical conduction is shown, which is not suitable for the channel of thin film transistors.

Coffee stains are a phenomenon due to convection in liquid drops, as described above, and can be suppressed by reducing convection in liquid drops. It is considered that making liquid drops smaller, increasing the viscosity of the dispersion liquid, and the like are effective in reducing convection in liquid drops. However, the boiling point of 1,2-dichloroethane is 83.7° C., which is low, and the vapor pressure is high, and hence, when trace amounts of liquid drops are to be ejected from the fine nozzles of ink jet or the like, fine liquid drops cannot be stably printed because 1,2-dichloroethane volatilizes inside the nozzles at room temperature. Further, the viscosity of 1,2-dichloroethane is 0.84 mPa·s, which is small, and such a small viscosity is also a factor that inhibits stable formation of liquid drops, and the formation of a uniform CNT network during drying.

It is an object of the present invention to provide a CNT dispersion liquid with high dispersion stability. It is another object of the present invention to provide a semiconductor device with excellent electrical characteristics by forming a current path including a random network of CNTs using a CNT dispersion liquid.

### Solution to Problem

One aspect of the present invention provides a carbon nanotube dispersion liquid obtained by mixing carbon nanotubes, a first organic solvent that is a nonpolar solvent, and a second organic solvent that has a polarity higher than that of the first organic solvent and is compatible with the first organic solvent.

In this carbon nanotube dispersion liquid, the carbon nanotubes are dispersed without using a dispersing agent.

Another aspect of the present invention provides a method for manufacturing a semiconductor device, the method including:

forming a gate electrode on a substrate;

forming a gate insulating film covering the gate electrode;

forming a source electrode and a drain electrode on both sides of the gate electrode; and

forming a semiconductor channel layer between the source electrode and the drain electrode such that the layer is in contact with the source electrode and the drain electrode, by a process including:

applying or printing the above carbon nanotube dispersion liquid, and drying.

### Advantageous Effects of Invention

According to the present invention, a stable dispersion liquid of CNTs can be obtained. In addition, the CNT dispersion liquid according to the present invention includes only components that can be removed by vaporization, other than CNTs. Therefore, a CNT random network formed using the CNT dispersion liquid according to the present invention is preferred for the current path of an electronic device, such as a thin film transistor, because substances that inhibit electrical conduction do not remain.

In addition, according to a manufacturing method using a CNT dispersion liquid in accordance with the present invention, a CNT random network with excellent uniformity can be formed, and thus, a semiconductor device with excellent electrical characteristics can be provided.

Further, according to a manufacturing method of forming a CNT random network by a printing method or an application method using a CNT dispersion liquid in accordance with the present invention, a large semiconductor device can be provided at low cost.

### BRIEF DESCRIPTION OF DRAWINGS

FIG. 1 shows observed images of a CNT dispersion liquid according to related art after printing and drying, measured by a conductive atomic force microscope (C-AFM). A height difference image is shown on the left side (A), and a current image is shown on the right side (B). In the current image, unevenly distributed dark color portions show actual current-carrying parts.

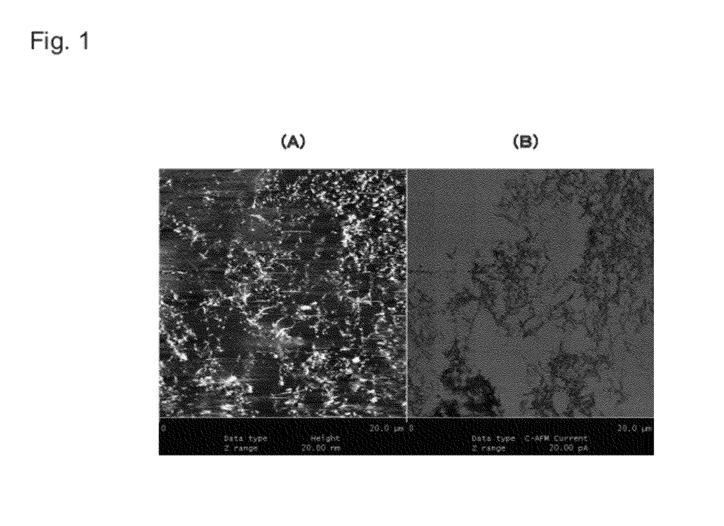

FIG. 2 shows observed images of the state, in which a coffee stain occurs, of a CNT dispersion liquid according to related art after printing and drying, measured by a conductive atomic force microscope (C-AFM). A height difference image is shown on the left side (A), and a current image is shown on the right side (B). In the current image, white portions show actual current-carrying parts.

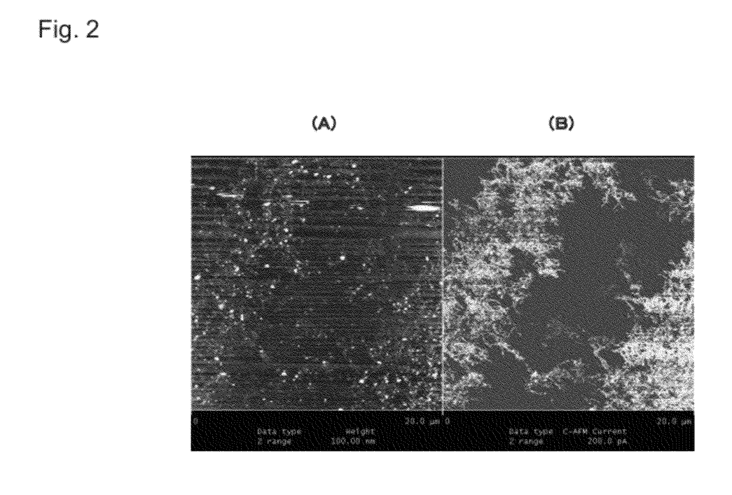

FIG. 3 is a diagram showing dispersion states of CNT dispersion liquids according to a first exemplary embodiment and comparative examples.

FIG. 4 is a diagram showing dispersion states of CNT dispersion liquids according to a second exemplary embodiment and comparative examples.

FIG. 5 is a diagram showing dispersion states of CNT dispersion liquids according to a third exemplary embodiment and comparative examples.

FIG. 6 is a diagram showing dispersion states of CNT dispersion liquids according to a fourth exemplary embodiment and a comparative example.

FIG. 7 is a diagram showing dispersion states of CNT dispersion liquids according to a fourth exemplary embodiment and a comparative example.

FIG. 8 is a schematic cross-sectional view of a field effect transistor in which a random network of CNTs formed using a CNT dispersion liquid according to an exemplary embodiment is applied to a channel layer.

FIG. 9 is an observed image (height difference image) of a random network of CNTs formed using a CNT dispersion liquid according to an exemplary embodiment, measured by a conductive atomic force microscope (C-AFM).

FIG. 10 is a diagram showing the transfer characteristics of a field effect transistor in which a random network of CNTs formed using a CNT dispersion liquid according to an exemplary embodiment is applied to a channel layer.

FIG. 11A is a diagram showing an example of a semiconductor device including a plurality of semiconductor elements according to an exemplary embodiment.

FIG. 11B is a diagram showing the configuration of the basic cell of a ferroelectric memory as a first example of a basic cell for the semiconductor device shown in FIG. 11A.

FIG. 11C is a diagram showing the configuration of the basic cell of a display as a second example of a basic cell for the semiconductor device shown in FIG. 11A.

FIG. 11D is a diagram showing the configuration of the basic cell of a sensor array apparatus as a third example of a basic cell for the semiconductor device shown in FIG. 11A.

### DESCRIPTION OF EMBODIMENTS

A carbon nanotube dispersion liquid (CNT dispersion liquid) according to this exemplary embodiment is obtained by mixing carbon nanotubes, a first organic solvent that is a nonpolar solvent, and a second organic solvent that has higher polarity than this first organic solvent and is compatible with this first organic solvent, and the carbon nanotubes are dispersed even without the addition of a dispersing agent.

The mass ratio of the first organic solvent to the second organic solvent is preferably in the range of 1/9 to 9/1, more preferably in the range of 1/4 to 4/1, in terms of obtaining a more stable dispersion liquid.

For the first organic solvent, hydrocarbons can be used. Hydrocarbons having a boiling point of 110° C. or more and 260° C. or less can be preferably used.

For the first organic solvent, aliphatic hydrocarbons can be used. For example, chain saturated hydrocarbons having 8 to 18 carbon atoms can be used. In particular, linear saturated hydrocarbons, for example, at least one solvent selected from n-decane, n-dodecane, and n-tetradecane, can be used.

In addition, for the first organic solvent, aromatic hydrocarbons can be used. For example, aromatic monocyclic hydrocarbons having 7 to 9 carbon atoms can be used. In particular, at least one solvent selected from toluene, xylene, and mesitylene can be used.

For the second organic solvent, a polar solvent compatible with the first organic solvent can be used.

For the second organic solvent, glymes can be used, and glymes having 4 to 12 carbon atoms are preferred. Examples of glymes include tetraethylene glycol dimethyl ether, diethylene glycol dibutyl ether, triethylene glycol dimethyl ether, diethylene glycol diethyl ether, diethylene glycol dimethyl ether, ethylene glycol diethyl ether, and ethylene glycol dimethyl ether. Among these, at least one solvent selected from triethylene glycol dimethyl ether, diethylene glycol diethyl ether, and diethylene glycol dimethyl ether is preferred.

In addition, for the second organic solvent, acetates can be used. For example, ethyl acetate and glycol acetates, particularly, at least one solvent selected from ethylene glycol monoethyl ether acetate and diethylene glycol monoethyl ether acetate can be used.

Also, for the second organic solvent, amides can be used. For example, at least one solvent selected from N-methyl-2-pyrrolidone and N,N-dimethylformamide can be used.

For the second organic solvent, alcohols can be also used. For example, monohydric aliphatic alcohols having 3 to 6 carbon atoms can be used. Particularly, isopropyl alcohol can be used.

For the second organic solvent, halogenated hydrocarbons can be also used. For example, halides of aliphatic hydrocarbons having 2 to 6 carbon atoms, particularly 1,2-dichloroethane, can be used.

In the present invention, as the first organic solvent, chain saturated hydrocarbons having 8 to 18 carbon atoms are preferred, linear saturated hydrocarbons having 8 to 18 carbon atoms are more preferred, and particularly, at least one solvent selected from n-decane, n-dodecane, and n-tetradecane is preferred, in terms of a boiling point, erosivity, handleability, and the like. As the second organic solvent, glymes and glycol acetates are preferred, glymes having 4 to 12 carbon atoms and glycol acetates having 5 to 8 carbon atoms are more preferred, and particularly, at least one or more solvents selected from triethylene glycol dimethyl ether, diethylene glycol diethyl ether, diethylene glycol dimethyl ether, ethylene glycol monoethyl ether acetate, and diethylene glycol monoethyl ether acetate are preferred, in terms of a boiling point, erosivity, and the like. Further, glymes are preferred, glymes having 4 to 12 carbon atoms are more preferred, and particularly, at least one or more solvents selected from triethylene glycol dimethyl ether, diethylene glycol diethyl ether, and diethylene glycol dimethyl ether are preferred, in terms of handleability and the like.

In the present invention, as the first organic solvent, a solvent with a relative dielectric constant of less than 2.5 can be used, and for the second organic solvent, a solvent with a relative dielectric constant larger than the relative dielectric constant of the first organic solvent can be used. In terms of obtaining a sufficient dispersion effect, the relative dielectric constant of the second organic solvent is preferably 3 or more, more preferably 4 or more, and further preferably 5 or more.

In the present invention, the boiling point of a mixed liquid of the first organic solvent and the second organic solvent is preferably 100° C. or more, more preferably 150° C. or more, and further preferably 200° C. or more, in terms of suppressing drying during printing or application to form a good current path (CNT random network). By using the mixed liquid with such a boiling point, particularly, the drying of nozzle portions can be suppressed in printing by an ink jet method, and good printing is possible. On the other hand, in terms of drying time after printing or after application, and performing recoating well, the boiling point of this mixed liquid is preferably 280° C. or less, more preferably 250° C. or less.

The CNT concentration in a CNT dispersion liquid according to the present invention is preferably 1 ppm or more, more preferably 5 ppm or more, in terms of forming a current path with more satisfactory electrical characteristics. On the other hand, in terms of the dispersion stability of the CNT dispersion liquid, and the uniformity of CNT distribution after printing or after application, the CNT concentration is preferably 100 ppm or less, more preferably 50 ppm or less.

“Dispersion” in the present invention means a state in which solids (CNTs) not dissolved in a solvent float or are suspended uniformly in the solvent (the mixed liquid of the first organic solvent and the second organic solvent). In addition, the “dispersion” in the present invention means that a dispersion state can be maintained for at least 70 hours immediately after the preparation of a dispersion liquid. A state in which solids being agglutinated and deposited in a particular portion in a liquid (for example, the bottom, the surface, or the region in the liquid) or the deposits being suspended can be visually observed is not referred to as dispersion.

In the present invention, the mixed liquid of the first organic solvent and the second organic solvent refers to one in a uniform liquid state in which the first organic solvent is compatible with the second organic solvent.

In a CNT dispersion liquid according to the present invention, CNTs are dispersed without using an ionic surfactant or a nonionic surfactant generally used as a dispersing agent for dispersing solid particles in a liquid. This CNT dispersion liquid can include only the first organic solvent, the second organic solvent, and CNTs. Thus, after the solvents are removed from the applied or printed CNT dispersion liquid, a CNT random network with excellent electrical characteristics, including only CNTs, can be formed without a dispersing agent remaining.

For a CNT used in the present invention, a Single Walled Carbon Nano Tube (SWCNT) having a single walled tube shape is preferred. Its diameter and length are not particularly limited, but one with a diameter of 0.7 nm to 2 nm and a length of 0.5 μm to 2.0 μm is preferably used. For the ends of SWCNTs, there are those whose end faces are open modified with a carboxyl group, a hydroxyl group, or the like, and those whose end faces are closed without being modified with a functional group. When SWCNTs are used in the present invention, the end structure is not limited.

Other components that can be vaporized together with the solvents may be added to a CNT dispersion liquid according to the present invention. For example, a subliming organic substance, such as naphthalene or adamantane, can be added as a thickening agent, and a highly volatile organic substance, such as azulene or guaiazulene, can be added as a coloring agent.

CNT dispersion liquids and a method for manufacturing a semiconductor device in accordance with exemplary embodiments of the present invention will be described below.

### First Exemplary Embodiment

In this exemplary embodiment, single walled CNTs (SWCNTs) were added in the proportion of 1 mg to 100 ml of each of mixed solvents using xylene as a nonpolar first organic solvent and using various polar organic solvents as a second organic solvent, and the mixtures were further ultrasonically irradiated to prepare CNT dispersion liquids with a concentration of about 10 ppm.

The single walled CNTs used here were previously subjected to strong acid treatment, and a minute metal catalyst used during the synthesis of the CNTs, and amorphous carbon and the like produced simultaneously with the CNTs were removed, and the purity of the CNTs was increased. It is generally known that in such single walled CNTs whose purity is increased through strong acid treatment, the surface is provided with a functional group, such as a carboxyl group, contributing to dispersibility. For the single walled CNTs, those fabricated by the Hipco (High Pressure Carbon monooxide) method (manufactured by CNI, purified grade, diameter: 1.0 to 1.2 nm, length: 1.0 to 1.5 μm) were used. Similar single walled CNTs were also used in exemplary embodiments described later.

For the mixed solvents in this exemplary embodiment, xylene (the dielectric constant of m-xylene: 2.374) was used as the nonpolar first organic solvent, and 1,2-dichloroethane (dielectric constant: 10.3), triethylene glycol dimethyl ether, diethylene glycol diethyl ether, diethylene glycol dimethyl ether (dielectric constant: 5.97), diethylene glycol monoethyl ether acetate, and N-methyl-2-pyrrolidone (dielectric constant: 32.0) were used as the second organic solvent mixed with the first organic solvent. The mixing ratio (mass ratio) of xylene, the first organic solvent, to the second organic solvent was 1:1.

As comparative examples, a dispersion liquid using n-tetradecane as a second organic solvent, and a dispersion liquid using mesitylene (dielectric constant: 2.279) as a second organic solvent were prepared. In addition, a dispersion liquid using xylene alone (a 100% xylene solvent) instead of the mixed solvents was prepared.

The dielectric constant of n-tetradecane can be estimated to be about 2 because the dielectric constant of n-dodecane and n-decane that are similarly alkanes and of a similar molecular structure is 2.016 and 1.991, respectively. In addition, the dielectric constant of triethylene glycol dimethyl ether and diethylene glycol diethyl ether can be estimated to be about 6 because the dielectric constant of diethylene glycol dimethyl ether that is similarly a glyme and has a plurality of similar ether bonds is 5.97. The dielectric constant of diethylene glycol monoethyl ether acetate can be estimated to be about 6 because the dielectric constant of ethyl acetate that is similarly an ester is 6.053.

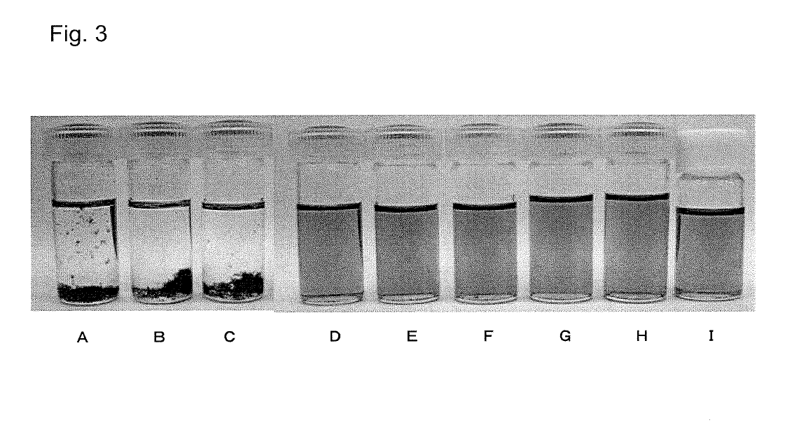

FIG. 3 shows the state of the CNT dispersion liquids after a lapse of 70 hours from ultrasonic irradiation.

In the CNT dispersion liquid (A) using the mixed liquid of xylene (the nonpolar first organic solvent) and n-tetradecane, the CNT dispersion liquid (B) using the mixed liquid of xylene and mesitylene, and the CNT dispersion liquid using the single solvent of xylene (C), CNTs aggregate together and precipitate.

On the other hand, in the CNT dispersion liquid (D) using the mixed liquid of xylene and 1,2-dichloroethane, the CNT dispersion liquid (E) using the mixed liquid of xylene and triethylene glycol dimethyl ether, the CNT dispersion liquid (F) using the mixed liquid of xylene and diethylene glycol diethyl ether, the CNT dispersion liquid (G) using the mixed liquid of xylene and diethylene glycol dimethyl ether, the CNT dispersion liquid (H) using the mixed liquid of xylene and diethylene glycol monoethyl ether acetate, and the CNT dispersion liquid (I) using the mixed liquid of xylene and N-methyl-2-pyrrolidone, CNTs are stably dispersed.

In this manner, in a mixed solvent of a nonpolar monocyclic aromatic hydrocarbon with a small dielectric constant and a polar organic solvent with a larger dielectric constant, CNTs can be stably dispersed without using a dispersing agent.

The solvents used here all have moderate vapor pressure at room temperature (25° C.), and therefore, by applying or printing a CNT dispersion liquid using such a mixed solvent, and drying it, a random network of CNTs suitable for a current path can be formed.

### Second Exemplary Embodiment

In this exemplary embodiment, single walled CNTs were added in the proportion of 1 mg to 100 ml of each of mixed solvents using n-tetradecane as a nonpolar first organic solvent and using various polar organic solvents as a second organic solvent, and the mixtures were further ultrasonically irradiated to prepare CNT dispersion liquids with a concentration of about 10 ppm.

For the single walled CNTs used here, single walled CNTs similar to those used in the first exemplary embodiment were used.

For the mixed solvents in this exemplary embodiment, n-tetradecane was used as the nonpolar first organic solvent, and 1,2-dichloroethane (dielectric constant: 10.3), triethylene glycol dimethyl ether, diethylene glycol diethyl ether, diethylene glycol dimethyl ether (dielectric constant: 5.97), and isopropyl alcohol (dielectric constant: 18.62) were used as the second solvent mixed with the first organic solvent. The mixing ratio (mass ratio) of n-tetradecane, the first organic solvent, to the second organic solvent was 1:1.

As comparative examples, a dispersion liquid using n-dodecane (dielectric constant: 2.016) as a second organic solvent, a dispersion liquid using n-decane (dielectric constant: 1.991) as a second organic solvent, a dispersion liquid using mesitylene (dielectric constant: 2.279) as a second organic solvent, and a dispersion liquid using xylene (the dielectric constant of m-xylene: 2.374) as a second organic solvent were prepared. In addition, as examples in which a mixed liquid is separated into layers, a dispersion liquid using diethylene glycol monoethyl ether acetate as a second organic solvent, and a dispersion liquid using N-methyl-2-pyrrolidone (dielectric constant: 32.0) as a second organic solvent were prepared. In addition, a dispersion liquid using n-tetradecane alone (a 100% n-tetradecane solvent) instead of the mixed solvents was prepared.

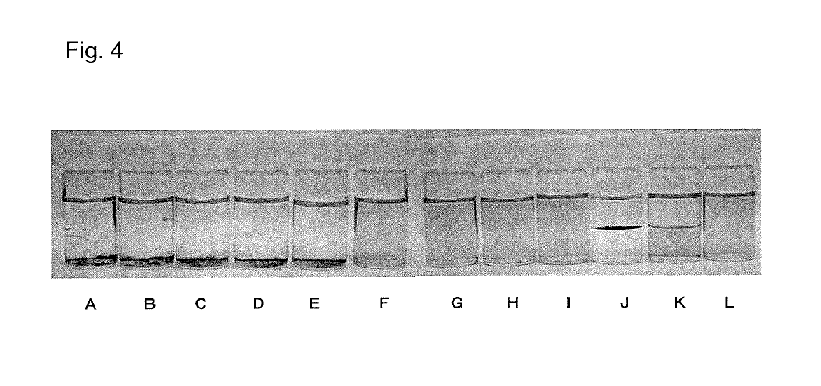

FIG. 4 shows the state of the CNT dispersion liquids after a lapse of 70 hours from ultrasonic irradiation.

In the CNT dispersion liquid (A) using the single solvent of n-tetradecane, the CNT dispersion liquid (B) using the mixed liquid of n-tetradecane (the nonpolar first organic solvent) and n-dodecane, the CNT dispersion liquid (C) using the mixed liquid of n-tetradecane and n-decane, the CNT dispersion liquid (D) using the mixed liquid of n-tetradecane and mesitylene, and the CNT dispersion liquid (E) using the mixed liquid of n-tetradecane and xylene, CNTs aggregate together and precipitate.

In addition, the CNT dispersion liquid (J) using the mixed liquid of n-tetradecane and diethylene glycol monoethyl ether acetate, and the CNT dispersion liquid (K) using the mixed liquid of n-tetradecane and N-methyl-2-pyrrolidone are separated into two layers.

On the other hand, in the CNT dispersion liquid (F) using the mixed liquid of n-tetradecane and 1,2-dichloroethane, the CNT dispersion liquid (G) using the mixed liquid of n-tetradecane and triethylene glycol dimethyl ether, the CNT dispersion liquid (H) using the mixed liquid of n-tetradecane and diethylene glycol diethyl ether, the CNT dispersion liquid (I) using the mixed liquid of n-tetradecane and diethylene glycol dimethyl ether, and the CNT dispersion liquid (L) using the mixed liquid of n-tetradecane and isopropyl alcohol, CNTs are stably dispersed.

In this manner, in a mixed solvent of a nonpolar alkane hydrocarbon with a small dielectric constant and a polar organic solvent with a larger dielectric constant, CNTs can be stably dispersed without using a dispersing agent unless the solvent is separated into two phases.

The solvents used here all have moderate vapor pressure at room temperature (25° C.), and therefore, by applying or printing a CNT dispersion liquid using such a mixed solvent, and drying it, a random network of CNTs suitable for a current path can be formed.

### Third Exemplary Embodiment

In this exemplary embodiment, single walled CNTs were added in the proportion of 1 mg to 100 ml of each of mixed solvents using 1,2-dichloroethane as a polar second organic solvent and using various nonpolar organic solvents as a first organic solvent, and the mixtures were further ultrasonically irradiated to prepare CNT dispersion liquids with a concentration of about 10 ppm.

For the single walled CNTs used here, single walled CNTs similar to those used in the first exemplary embodiment were used.

For the mixed solvents in this exemplary embodiment, 1,2-dichloroethane (dielectric constant: 10.3) was used as the polar second organic solvent, and n-tetradecane, mesitylene (dielectric constant: 2.279), and xylene (the dielectric constant of m-xylene: 2.374) were used as the first organic solvent. The mixing ratio (mass ratio) of the first organic solvent to 1,2-dichloroethane, the second organic solvent, was 1:1.

As comparative examples, a dispersion liquid using triethylene glycol dimethyl ether as a first organic solvent, a dispersion liquid using diethylene glycol diethyl ether as a first organic solvent, a dispersion liquid using diethylene glycol dimethyl ether (dielectric constant: 5.97) as a first organic solvent, a dispersion liquid using diethylene glycol monoethyl ether acetate as a first organic solvent, a dispersion liquid using N-methyl-2-pyrrolidone (dielectric constant: 32.0) as a first organic solvent, and a dispersion liquid using isopropyl alcohol (dielectric constant: 18.62) as a first organic solvent were prepared. In addition, a dispersion liquid using 1,2-dichloroethane alone (a 100% 1,2-dichloroethane solvent) instead of the mixed solvent was prepared.

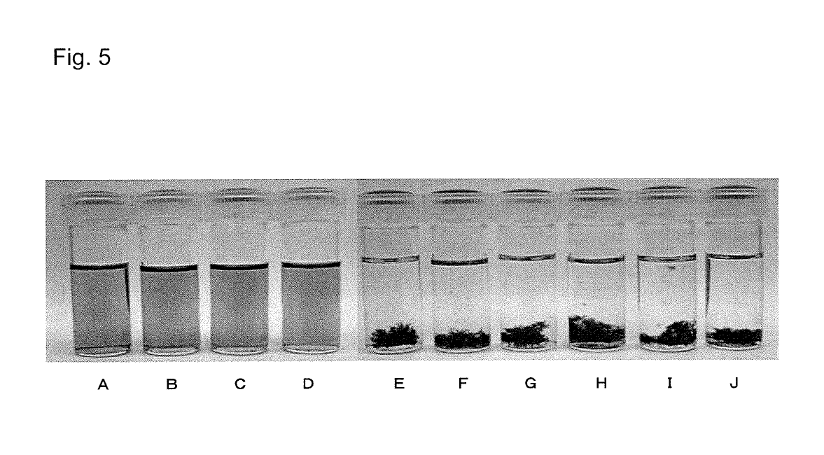

FIG. 5 shows the state of the CNT dispersion liquids after a lapse of 70 hours from ultrasonic irradiation.

In the CNT dispersion liquid (A) using the mixed liquid of 1,2-dichloroethane (the polar second organic solvent) and n-tetradecane, the CNT dispersion liquid (B) using the mixed liquid of 1,2-dichloroethane and mesitylene, and the CNT dispersion liquid (C) using the mixed liquid of 1,2-dichloroethane and xylene, CNTs are stably dispersed. In addition, in the CNT dispersion liquid (D) using the single solvent of 1,2-dichloroethane, CNTs are dispersed as described above.

On the other hand, in the CNT dispersion liquid (E) using the mixed liquid of 1,2-dichloroethane and triethylene glycol dimethyl ether, the CNT dispersion liquid (F) using the mixed liquid of 1,2-dichloroethane and diethylene glycol diethyl ether, the CNT dispersion liquid (G) using the mixed liquid of 1,2-dichloroethane and diethylene glycol dimethyl ether, the CNT dispersion liquid (H) using the mixed liquid of 1,2-dichloroethane and diethylene glycol monoethyl ether acetate, the CNT dispersion liquid (I) using the mixed liquid of 1,2-dichloroethane and N-methyl-2-pyrrolidone, and the CNT dispersion liquid (J) using the mixed liquid of 1,2-dichloroethane and isopropyl alcohol, CNTs aggregate together and precipitate.

In this manner, in a mixed solvent of a nonpolar alkane hydrocarbon or monocyclic aromatic hydrocarbon with a small dielectric constant and 1,2-dichloroethane with a larger dielectric constant, CNTs can be stably dispersed without using a dispersing agent.

The solvents used in this exemplary embodiment all have moderate vapor pressure at room temperature (25° C.), and therefore, by applying or printing a CNT dispersion liquid using such a mixed solvent, and drying it, a random network of CNTs suitable for a current path can be formed.

### Fourth Exemplary Embodiment

In this exemplary embodiment, using n-tetradecane as a nonpolar first organic solvent and triethylene glycol dimethyl ether as a polar second organic solvent, dispersion liquids with different mixing ratios (mass ratios) of the first organic solvent to the second organic solvent were prepared.

Single walled CNTs were added in the proportion of 1 mg to 100 ml of each of the mixed solvents, and the mixtures were further ultrasonically irradiated to prepare CNT dispersion liquids with a concentration of about 10 ppm. For the single walled CNTs used here, single walled CNTs similar to those used in the first exemplary embodiment were used.

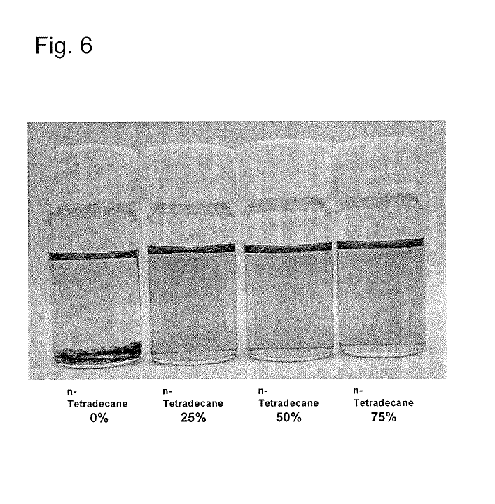

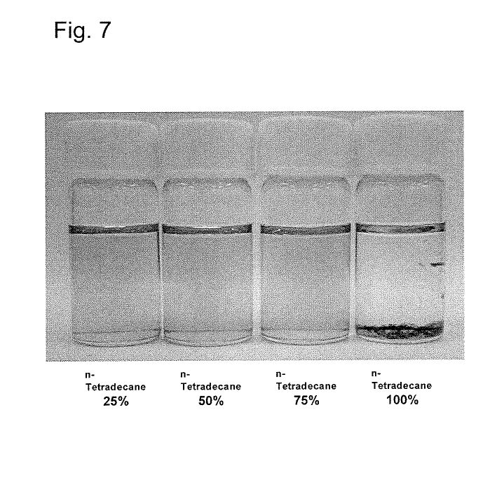

FIG. 6 shows the dispersion state of the CNT dispersion liquids in which the proportion (% by mass) of n-tetradecane is 0% (the proportion of triethylene glycol dimethyl ether is 100%), 25%, 50%, and 75%. FIG. 7 shows the dispersion state of the CNT dispersion liquids in which the proportion (% by mass) of n-tetradecane is 25%, 50%, 75%, and 100% (the proportion of triethylene glycol dimethyl ether is 0%). The state of all CNT dispersion liquids is a state after a lapse of 70 hours from ultrasonic irradiation. As is clear from these figures, the CNT dispersion liquids using the mixed solvents show stable dispersibility regardless of the mixing ratios of the mixed solvents. Such high flexibility of the mixing ratio allows solvent design according to the utilization form of a CNT dispersion liquid and can widen the range of application of CNT dispersion liquids.

Alkanes such as n-tetradecane and glymes such as triethylene glycol dimethyl ether used this exemplary embodiment both have a linear molecular structure, and there is a tendency that as the molecular weight becomes larger, the molecular chain becomes longer, and the viscosity and the boiling point both become higher. Therefore, by appropriately changing the types and mixing ratio of the solvents, it is possible to adjust the viscosity and the boiling point according to the method of the application or printing of the CNT dispersion liquid in the formation of a CNT random network.

For example, when an application method, such as a spin coating method, is used, a uniform CNT random network is easily formed when the viscosity of the CNT dispersion liquid is set low and the boiling point of the solvents is set low. In such a case, low molecular weight alkanes and glymes are suitable.

On the other hand, when a printing and drawing method in which minute liquid drops are ejected from fine nozzles, such as an ink jet printer or a dispenser, is used, the solvents volatilize in the fine nozzles if the boiling point of the solvents is low, and the nozzles are easily clogged. In addition, when the viscosity of the solvents is high, the shape of liquid drops during ejection is stable, and further, the stability of a printed and drawn pattern after liquid drops reach a substrate is also high. Therefore, when such a printing and drawing method is used, alkanes and glymes with high boiling points, larger viscosity, and large molecular weight are suitable.

The boiling point of n-tetradecane and triethylene glycol dimethyl ether used in this exemplary embodiment is 252.5° C. and 216° C., respectively. A CNT dispersion liquid using a mixed solvent of these does not volatilize easily in nozzles during printing and allows stable printing. In addition, the coefficient of viscosity of n-tetradecane and triethylene glycol dimethyl ether is 2.06 CP (mPa·s) and 3.80 CP (mPa·s), respectively, which are large, providing an excellent shape of liquid drops during ejection and excellent stability of a printed and drawn pattern. Both solvents have sufficient vapor pressure at room temperature, and the surfaces of fine liquid drops of both solvents are active, and therefore, there is no practical problem in the evaporation and drying of the solvents in a printed and drawn pattern on a substrate. Holding in a reduced pressure environment after printing is particularly effective for drying at higher speed. It is also possible to volatilize the remaining solvent components by further holding in a high temperature environment at about 180° C. after drying.

Further, CNT dispersion liquids using mixed solvents of alkanes and glymes have the following advantages. First, the CNT dispersion liquids are advantageous in terms of a work environment. The environmental load of the mixed solvents is lower than that of solvents including aromatic hydrocarbons and halogens, which is a large advantage particularly when large semiconductor devices, such as large area displays, are manufactured by an application method or a printing method. Secondly, the erosivity for other resin materials is low. For example, polyimide resins that are provided as liquid materials and cured at low temperature are eroded by amide solvents, such as N-methyl-2-pyrrolidone, but are resistant to alkanes and glymes. When an electronic device is manufactured by a printing method, it is necessary to layer and dispose various materials, such as metals, semiconductors, and insulators. Low erosivity for materials is an extremely important advantage in the manufacture of an electronic device.

In this manner, a CNT dispersion liquid according to the present invention is formed using a mixed solvent in which two types or more of solvents are combined. By appropriately selecting the types and mixing ratio of the solvents forming this mixed solvent, it is possible to provide and adjust characteristics according to the use while ensuring dispersibility. In particular, when a random network of CNTs is printed and formed in the manufacture of an electronic device, it is possible to prepare a dispersion liquid considering the boiling point, vapor pressure, viscosity, erosivity for materials, and the like of the solvents. As a result, it is possible to provide a CNT dispersion liquid with excellent printing properties and CNT dispersibility.

In addition, the characteristics of a CNT dispersion liquid according to the present invention can be further improved by adding additives that can be vaporized with the solvents, as required. For example, when a solid having a sublimation point of 220° C. or less, such as naphthalene or adamantane, is added, the viscosity of the CNT dispersion liquid is increased, and the solid component that is deposited when printed liquid drops dry fixes CNTs, and thus, the printing precision is improved. The naphthalene or the adamantane can then be sufficiently sublimed by heat treatment at about 200° C. and is not a factor that inhibits the electrical conduction of a CNT random network. In addition, the addition of a colored organic substance including no metal element, such as azulene or guaiazulene, is also effective. For example, the amount of CNTs used for the semiconductor channel of a thin film transistor is very small, and it is difficult to check the presence of CNTs by an ordinary optical microscope or the like. When azulene or guaiazulene is added to the CNT dispersion liquid, a region where the CNT dispersion liquid is printed is easily checked by an optical microscope or the like due to a color emitted by the azulene or the guaiazulene. Unlike ordinary pigments containing metal ions, azulene or guaiazulene can be sufficiently volatilized by heat treatment at about 200° C. Therefore, the azulene or the guaiazulene can be removed after the region where the CNT dispersion liquid is printed is checked, and a CNT random network showing good electrical conductivity can be obtained.

### Fifth Exemplary Embodiment

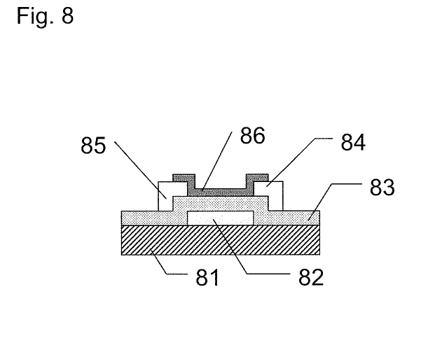

FIG. 8 shows a cross-sectional structure of a semiconductor element fabricated using a CNT dispersion liquid (CNT concentration: 10 ppm) in accordance with an exemplary embodiment. This semiconductor element is a field effect transistor using a random network of CNTs for a channel layer.

As shown in FIG. 8, a gate electrode 82 is formed on a supporting substrate 81, and a gate insulating film 83 is formed so as to cover the gate electrode 82. A source electrode 84 and a drain electrode 85 are disposed on this gate insulating film 83 at a distance corresponding to channel length. Further, a random network of CNTs as a channel layer 86 is disposed in contact with the gate insulating film 83, the source electrode 84, and the drain electrode 85.

The semiconductor element of the above structure is fabricated, for example, by the following fabrication method.

First, the desired shape of the gate electrode 82 is drawn on a 0.2 mm thick polyimide substrate 81 with a dispersion liquid of silver nanoparticles dispersed in a solvent, as an ink, using, for example, an ink jet printer, and the dispersion liquid is dried.

Next, heat treatment is performed at 200° C. to obtain the sintered gate electrode 82.

Next, an insulator made of an organic polymer is applied so as to cover the above gate electrode 82, and densified at 180° C. to form the gate insulating film 83. The film thickness of this gate insulating film 83 is not particularly limited but is preferably in the range of 10 to 1000 nm because if the film thickness is too thin, it is difficult to effectively suppress leak current between the gate electrode and other electrodes, and if the film thickness is too thick, the switching phenomenon of the active layer depending on gate bias voltage cannot be effectively controlled.

When the source electrode 84 and the drain electrode 85 are formed, a dispersion liquid of silver nanoparticles dispersed in a solvent, as an ink, is drawn in the desired shapes of the electrodes using, for example, an ink jet printer, and dried. Next, heat treatment is performed at 180° C. to obtain sintered electrodes.

Single walled CNTs highly purified by strong acid treatment are mixed with a mixed solvent of 75% by mass of n-tetradecane and 25% by mass of triethylene glycol dimethyl ether, and the mixture is ultrasonically irradiated to prepare a CNT dispersion liquid (CNT ink). Then, the CNT ink is applied between the source electrode 84 and the drain electrode 85 using a dispenser, and dried.

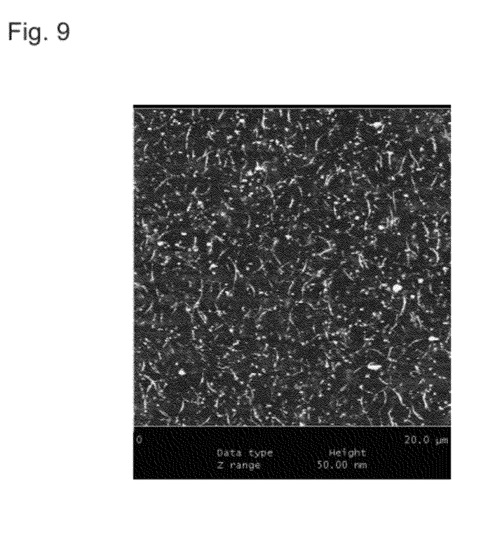

FIG. 9 shows an observed image (height difference image) obtained by a C-AFM after the CNT ink is dropped on polyimide and dried. It is seen that CNTs (white portions) are uniformly disposed. In order to uniformly dispose CNTs in this manner by a printing method, it is necessary to satisfy many conditions, such as the CNTs being stably dispersed in the CNT ink, ink ejection during printing being stable, and appropriate drying conditions being provided. It is confirmed that the CNT dispersion liquid in accordance with this exemplary embodiment satisfies such requirements. The density of the CNTs in this observed image obtained by the C-AFM is low, and the number of the mutual connection points of the CNTs is small. Further, by recoating the CNT ink, a random network of CNTs is formed, and a good semiconductor channel is formed.

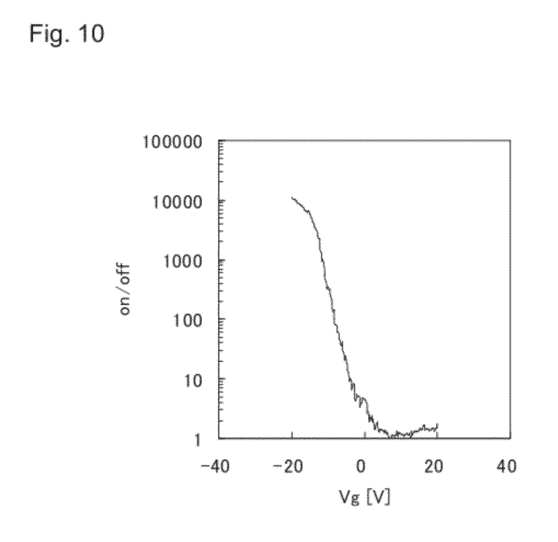

FIG. 10 shows the transfer characteristics of a CNT thin film transistor fabricated in this manner using a printing method. When the gate voltage on the horizontal axis is positively increased, the drain current on the vertical axis decreases. On the contrary, when the gate voltage is negatively increased, the drain current increases. In other words, p-type transistor characteristics are obtained. An on/off ratio of about 10⁴ is obtained. By using the CNT dispersion liquid in accordance with this exemplary embodiment, a CNT thin film transistor with such high performance can be manufactured by a printing method.

### Sixth Exemplary Embodiment

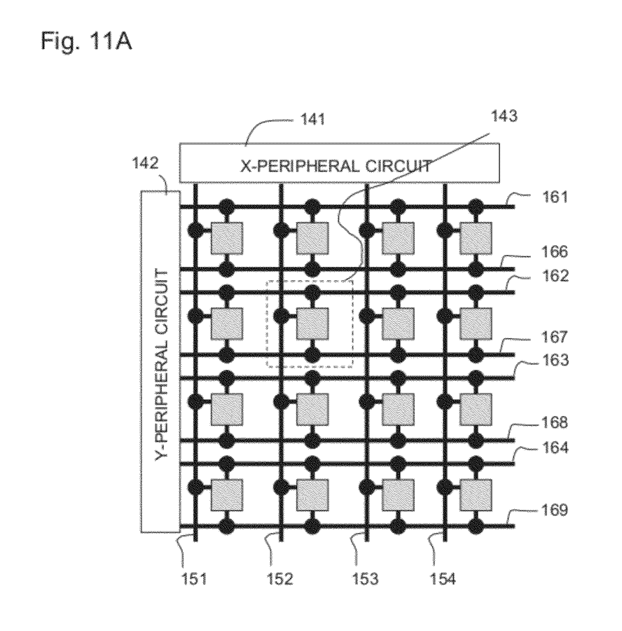

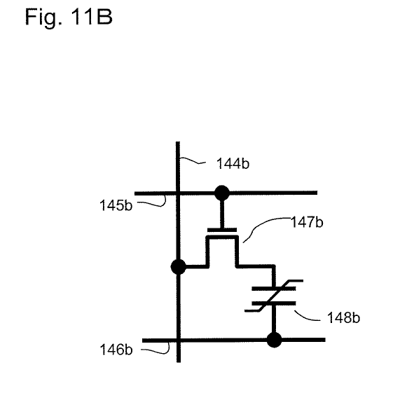

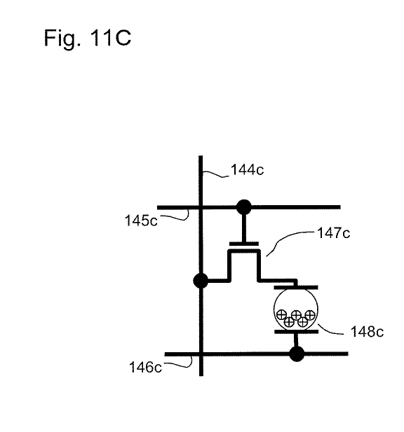

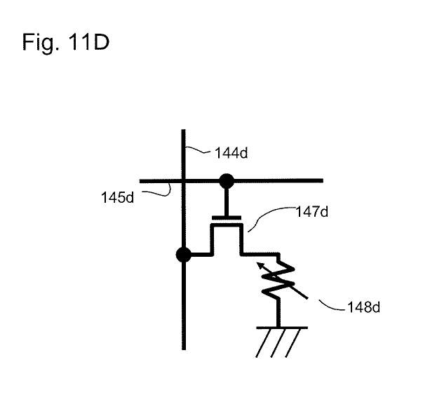

FIG. 11A shows an example of a semiconductor device including a plurality of semiconductor elements according to an exemplary embodiment. FIG. 11B to FIG. 11D show examples of a basic cell forming this semiconductor device.

This semiconductor device includes a plurality of bit lines 151 to 154, and a plurality of word lines 161 to 164 and a plurality of plate lines 166 to 169 orthogonal to the bit lines. One ends of the bit lines 151 to 154 are connected to an X-peripheral circuit 141, and one ends of the word lines 161 to 164 and the plate lines 166 to 169 are connected to a Y-peripheral circuit 142. The X-peripheral circuit 141 and the Y-peripheral circuit 142 each include a decoder circuit, a driver circuit, an On/Off switch, and the like. Basic cells 143 are disposed in regions where the bit lines 151 to 154 intersect with the word lines 161 to 164 and the plate lines 166 to 169, respectively. In FIG. 11A, the basic cells 143 are disposed in a 4×4 matrix. The basic cells 143 each include three connection points, and the connection points are connected to the bit line, the word line, and the plate line, respectively. For example, the basic cell surrounded by the broken line in FIG. 11A is connected to the bit line 152, the word line 162, and the plate line 167.

FIG. 11B shows an example of the basic cell 143. In this example, the basic cell includes one field effect transistor 147b and a ferroelectric capacitor 148b connected in series with this field effect transistor 147b. The other terminal of the ferroelectric capacitor 148b is connected to the plate line 146b. The other terminal of the field effect transistor 147b is connected to the bit line 144b, and the gate electrode of the field effect transistor 147b is connected to the word line 145b. The field effect transistor 147b is a select transistor, and the thin film transistor according to the fifth exemplary embodiment is used. By the action of this field effect transistor 147b, the predetermined ferroelectric capacitor 148b is selected in the two-dimensional array. A prescribed voltage determined by the potential difference between the bit line 144b and the plate line 146b is applied to the selected ferroelectric capacitor 148b, providing function as a ferroelectric RAM. The transistor of each basic cell can be fabricated on a plastic substrate by a printing method as in the fifth exemplary embodiment, and therefore, a large area ferroelectric RAM can be inexpensively manufactured.

FIG. 11C shows a second example of the basic cell 143. In this example, the basic cell includes one field effect transistor 147c and an electrophoretic microcapsule 148c, the so-called electronic ink, connected in series with this field effect transistor 147c. The other terminal of the electrophoretic microcapsule 148c is connected to the plate line 146c. The other terminal of the field effect transistor 147c is connected to the bit line 144c, and the gate electrode of the field effect transistor 147c is connected to the word line 145c. The field effect transistor 147c is a select transistor, and the thin film transistor according to the fifth exemplary embodiment is used. By the action of this field effect transistor 147c, the predetermined electrophoretic microcapsule 148c is selected in the two-dimensional array. A prescribed voltage determined by the potential difference between the bit line 144c and the plate line 146c is applied to the selected electrophoretic microcapsule 148c, and the display state of the electrophoretic microcapsule 148c can be changed. The transistor of each basic cell can be fabricated on a plastic substrate by a printing method as in the fifth exemplary embodiment, and therefore, a large area flexible display can be inexpensively manufactured.

FIG. 11D shows a third example of the basic cell 143. In this example, the basic cell includes one field effect transistor 147d and a variable resistance 148d connected in series with this field effect transistor 147d. The other terminal of the variable resistance 148d is grounded. The other terminal of the field effect transistor 147d is connected to the bit line 144d, and the gate electrode of the field effect transistor 147d is connected to the word line 145d. The field effect transistor 147d is a select transistor, and the thin film transistor according to the fifth exemplary embodiment is used. By the action of this field effect transistor 147d, the predetermined variable resistance 148d is selected in the two-dimensional array. A constant current or a constant voltage is applied to the selected variable resistance 148d from the X-peripheral circuit 141 (FIG. 11A) via the bit line 144d and the field effect transistor 147d, and the resistance value of the variable resistance 148d is detected. As the variable resistance 148d, one whose resistance value is changed by a magnetic field or pressure can be used. In other words, this semiconductor device is a sensor array that can examine the two-dimensional distribution of a magnetic field or pressure. The transistor of each basic cell can be fabricated on a plastic substrate by a printing method as in the fifth exemplary embodiment, and therefore, a large area flexible sensor array can be inexpensively manufactured.

While the present invention has been described with reference to the exemplary embodiments, the present invention is not limited to the above embodiments. Various changes that can be understood by those skilled in the art may be made to the constitution and details of the present invention within the scope thereof.

This application claims the right of priority based on Japanese Patent Application No. 2010-009253 filed Jan. 19, 2010, the entire content of which is incorporated herein by reference.

### REFERENCE SIGNS LIST

81 supporting substrate
82 gate electrode
83 gate insulating film
84 source electrode
85 drain electrode
86 channel layer
141 X-peripheral circuit
142 Y-peripheral circuit
143 basic cell
151 to 154 bit lines
161 to 164 word lines
166 to 169 plate lines
144b bit line
145b word line
146b plate line
147b field effect transistor
148b ferroelectric capacitor
144c bit line
145c word line
146c plate line
147c field effect transistor
148c electrophoretic microcapsule
144d bit line
145d word line
146d plate line
147d field effect transistor
148d variable resistance

1. A carbon nanotube dispersion liquid obtained by mixing carbon nanotubes, a first organic solvent being a nonpolar solvent, and a second organic solvent having a polarity higher than that of the first organic solvent and being compatible with the first organic solvent.

2. The carbon nanotube dispersion liquid according to claim 1, wherein the carbon nanotubes are dispersed without using a dispersing agent.

3. The carbon nanotube dispersion liquid according to claim 1, wherein a content of the carbon nanotubes is in a range of 1 ppm to 100 ppm.

4. The carbon nanotube dispersion liquid according to claim 1, wherein a mass ratio of a content of the first organic solvent to that of the second organic solvent is in a range of 1/9 to 9/1.

5. The carbon nanotube dispersion liquid according to claim 1, wherein a boiling point of a mixed liquid of the first organic solvent and the second organic solvent is in a range of 100° C. to 280° C.

6. The carbon nanotube dispersion liquid according to claim 1, wherein a relative dielectric constant of the first organic solvent is less than 2.5, and a relative dielectric constant of the second organic solvent is 3 or more.

7. The carbon nanotube dispersion liquid according to claim 1, wherein the first organic solvent is a hydrocarbon having a boiling point of 110° C. or more and 260° C. or less.

8. The carbon nanotube dispersion liquid according to claim 1, wherein the first organic solvent is a chain saturated hydrocarbon having 8 to 18 carbon atoms.

9. The carbon nanotube dispersion liquid according to claim 1, wherein the first organic solvent is at least one solvent selected from the group consisting of n-decane, n-dodecane, and n-tetradecane.

10. The carbon nanotube dispersion liquid according to claim 1, wherein the first organic solvent is an aromatic monocyclic hydrocarbon having 7 to 9 carbon atoms.

11. The carbon nanotube dispersion liquid according to claim 1, wherein the first organic solvent is at least one solvent selected from the group consisting of toluene, xylene, and mesitylene.

12. The carbon nanotube dispersion liquid according to claim 1, wherein the second organic solvent is a glyme having 4 to 12 carbon atoms.

13. The carbon nanotube dispersion liquid according to claim 1, wherein the second organic solvent is at least one solvent selected from the group consisting of triethylene glycol dimethyl ether, diethylene glycol diethyl ether, and diethylene glycol dimethyl ether.

14. The carbon nanotube dispersion liquid according to claim 1, wherein the second organic solvent is a glycol acetate having 5 to 8 carbon atoms.

15. The carbon nanotube dispersion liquid according to claim 1, wherein the second organic solvent is at least one solvent selected from the group consisting of ethylene glycol monoethyl ether acetate and diethylene glycol monoethyl ether acetate.

16. The carbon nanotube dispersion liquid according to claim 1, wherein the second organic solvent is an amide.

17. The carbon nanotube dispersion liquid according to claim 1, wherein the second organic solvent is at least one solvent selected from the group consisting of N-methyl-2-pyrrolidone and N,N-dimethylformamide.

18. The carbon nanotube dispersion liquid according to claim 1, wherein the second organic solvent is a monohydric aliphatic alcohol having 3 to 6 carbon atoms.

19. The carbon nanotube dispersion liquid according to claim 1, wherein the second organic solvent is isopropyl alcohol.

20. The carbon nanotube dispersion liquid according to claim 1, wherein the second organic solvent is a halogenated aliphatic hydrocarbon having 2 to 6 carbon atoms.

21. The carbon nanotube dispersion liquid according to claim 1, wherein the second organic solvent is 1,2-dichloroethane.

22. The carbon nanotube dispersion liquid according to claim 1, wherein a subliming organic substance having a sublimation point of 220° C. or less is added.

23. The carbon nanotube dispersion liquid according to claim 1, wherein azulene or guaiazulene is added.

24. The carbon nanotube dispersion liquid according to claim 1, wherein the carbon nanotubes are single walled carbon nanotubes.

25. A method for manufacturing a semiconductor device, the method comprising:
forming a gate electrode on a substrate;
forming a gate insulating film covering the gate electrode;
forming a source electrode and a drain electrode on both sides of the gate electrode; and
forming a semiconductor channel layer between the source electrode and the drain electrode such that the layer is in contact with the source electrode and the drain electrode, by a process comprising:
applying or printing a carbon nanotube dispersion liquid of claim 1, and drying.

26. A carbon nanotube dispersion liquid comprising:
carbon nanotubes; and
a mixed organic solvent obtained by mixing a first organic solvent being a nonpolar solvent, and a second organic solvent having a polarity higher than that of the first organic solvent and being compatible with the first organic solvent,
wherein the carbon nanotubes are dispersed in the mixed organic solvent without using a dispersing agent.

27. The carbon nanotube dispersion liquid according to claim 26, wherein the first organic solvent is a chain saturated hydrocarbon having 8 to 18 carbon atoms.

28. The carbon nanotube dispersion liquid according to claim 26, wherein the first organic solvent is at least one solvent selected from the group consisting of n-decane, n-dodecane, and n-tetradecane.

29. The carbon nanotube dispersion liquid according to claim 27, the second organic solvent is at least one solvent selected from the group consisting of a glyme having 4 to 12 carbon atoms and a glycol acetate having 5 to 8 carbon atoms.

30. The carbon nanotube dispersion liquid according to claim 27, the second organic solvent is at least one solvent selected from the group consisting of triethylene glycol dimethyl ether, diethylene glycol diethyl ether, diethylene glycol dimethyl ether, ethylene glycol monoethyl ether acetate, and diethylene glycol monoethyl ether acetate.

31. The carbon nanotube dispersion liquid according to claim 26, wherein a content of the carbon nanotubes is in a range of 1 ppm to 100 ppm.

32. The carbon nanotube dispersion liquid according to claim 26, wherein a mass ratio of a content of the first organic solvent to that of the second organic solvent is in a range of 1/9 to 9/1.

33. The carbon nanotube dispersion liquid according to claim 26, further comprising a subliming organic substance dissolved in the mixed organic solvent.

34. The carbon nanotube dispersion liquid according to claim 26, further comprising an additive dissolved in the mixed organic solvent, the additive being selected from the group consisting of naphthalene, adamantane, azulene, and guaiazulene.
